(19) United States
(12) Patent Application Publication
(10) Pub. No.: US 2026/0037697 A1
(43) Pub. Date: Feb. 5, 2026

(54) PREDICTION MODEL CREATION APPARATUS

(71) Applicant: NEC Corporation, Tokyo (JP)

(72) Inventors: Ryuta Matsuno, Tokyo (JP); Keita Sakuma, Tokyo (JP); Masakazu Hirokawa, Tokyo (JP)

(73) Assignee: NEC Corporation, Tokyo (JP)

(21) Appl. No.: 19/270,786

(22) Filed: Jul. 16, 2025

(30) Foreign Application Priority Data
Jul. 31, 2024 (JP) 2024-124440

(51) Int. Cl. G06F 30/27

(52) U.S. Cl. CPC G06F 30/27

(57) ABSTRACT

A prediction model creation apparatus of the present disclosure includes: an acquiring unit acquiring training data including averaged samples each obtained by averaging a plurality of samples each composed of a pair of an explanatory variable and an objective variable; an estimating unit estimating a pre-averaging distribution that is a distribution of explanatory variables before averaging corresponding to explanatory variables composing the averaged samples of the training data; and a training unit performing machine learning on a prediction model that predicts an objective variable from an explanatory variable, based on the training data and the pre-averaging distribution for decision making support.

### INCORPORATION BY REFERENCE

This application is based upon and claims the benefit of priority from Japanese patent application No. 2024-124440, filed on Jul. 31, 2024, the disclosure of which is incorporated herein in its entirety by reference.

### TECHNICAL FIELD

The present disclosure relates to a prediction model creation apparatus.

### BACKGROUND ART

It is practiced in various fields to make a prediction on input data using a machine learning model. For example, Patent Literature 1 describes performing determination prediction for loan screening and determination prediction for patient's disease using a machine learning model that has learned from past case data. As a specific example, in Patent Literature 1, a machine learning model is created by machine learning from case data such as the patient's gender, age, and implementation of a medical procedure.

### CITATION LIST

### Patent Literature

[Patent Literature 1] Japanese Unexamined Patent Application Publication No. JP 2022-076345A

### SUMMARY OF INVENTION

### Technical Problem

However, the technique described in Patent Literature 1 uses personal information such as the patient's age and implementation of a medical procedure as training data for machine learning, which may lead to the risk of leakage of such personal information. For example, there is a risk of personal information leaking from training data itself or personal information leaking from a machine learning model. As a result, in the case of creating a prediction model using case data, there is a risk of leakage of raw data containing personal information, which may lead to a problem of reduced security.

Accordingly, an object of the present disclosure is to solve the aforementioned problem, which is reduced security that may occur in the case of creating a prediction model using machine learning.

### Solution to Problem

A prediction model creation apparatus as an aspect of the present disclosure includes: an acquiring unit acquiring training data including averaged samples each obtained by averaging a plurality of samples each composed of a pair of an explanatory variable and an objective variable; an estimating unit estimating a pre-averaging distribution that is a distribution of explanatory variables before averaging corresponding to explanatory variables composing the averaged samples of the training data; and a training unit performing machine learning on a prediction model that predicts an objective variable from an explanatory variable, based on the training data and the pre-averaging distribution.

Further, a prediction model creation method as an aspect of the present disclosure includes: acquiring training data including averaged samples each obtained by averaging a plurality of samples each composed of a pair of an explanatory variable and an objective variable; estimating a pre-averaging distribution that is a distribution of explanatory variables before averaging corresponding to explanatory variables composing the averaged samples of the training data; and performing machine learning on a prediction model that predicts an objective variable from an explanatory variable, based on the training data and the pre-averaging distribution.

Further, a program as an aspect of the present disclosure includes instructions for causing a computer to execute processes to: acquire training data including averaged samples each obtained by averaging a plurality of samples each composed of a pair of an explanatory variable and an objective variable; estimate a pre-averaging distribution that is a distribution of explanatory variables before averaging corresponding to explanatory variables composing the averaged samples of the training data; and perform machine learning on a prediction model that predicts an objective variable from an explanatory variable, based on the training data and the pre-averaging distribution.

### Advantageous Effects of Invention

With the configurations as described above, the present disclosure can achieve increase of security in the case of creating a prediction model by machine learning.

### BRIEF DESCRIPTION OF DRAWINGS

FIG. 1 is a block diagram showing an example of a configuration of a prediction model creation apparatus according to the present disclosure.

FIG. 2 is a flowchart showing an example of processing operation of the prediction model creation apparatus according to the present disclosure.

FIG. 3 is a block diagram showing an example of a configuration and a processing state of an information processing system according to the present disclosure.

FIG. 4 is a block diagram showing an example of a hardware configuration of a prediction model creation apparatus according to the present disclosure.

FIG. 5 is a block diagram showing an example of a configuration of a prediction model creation apparatus according to the present disclosure.

### EXAMPLE EMBODIMENTS

### First Example Embodiment

A first example embodiment of the present disclosure will be described with reference to the drawings. The drawings may be related to any example embodiment.

A prediction model creation apparatus 10 according to this example embodiment performs machine learning with training data and creates a prediction model that predicts an objective variable from an explanatory variable. In particular, in this example embodiment, a prediction model is created, not using raw data of cases as training data, but using an averaged sample obtained by averaging a plurality of samples, which are the raw data, as training data. This allows for the suppression of leakage of raw data such as personal information as training data, thus enabling achievement of increase of security.

Here, in this example embodiment, a case of performing determination prediction of loan screening for an individual will be described as an example of prediction by a prediction model. In this case, explanatory variables input into the prediction model are the age, annual income, saving deposit, place of work, years of service and so forth of an individual, and an objective variable output from the prediction model is credit approval or denial, such as loan approval or denial. However, the prediction by the prediction model in the present disclosure is not limited to the determination prediction of loan screening mentioned above, and may be a prediction of any content. That is to say, explanatory variables input into the prediction model and an objective variable output from the prediction model are not limited to the information mentioned above.

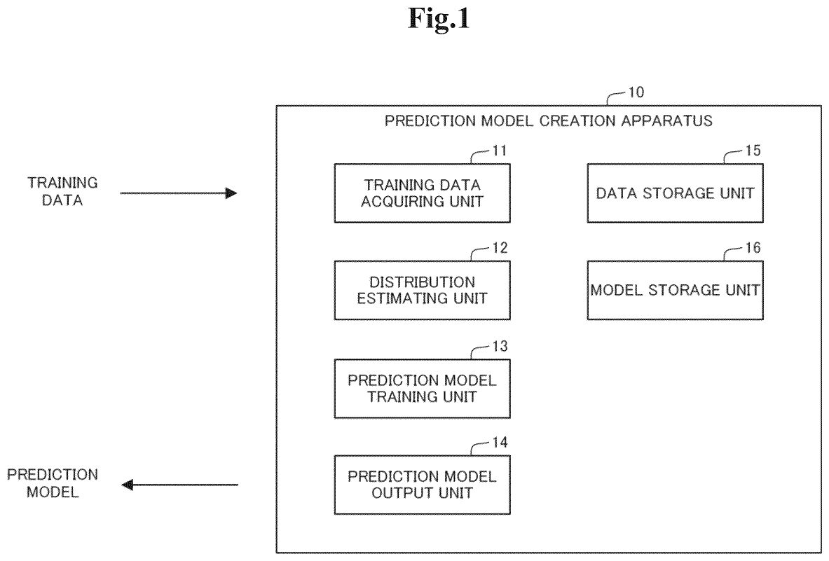

The configuration and operation of the prediction model creation apparatus 10 according to this example embodiment will be described below. The prediction model creation apparatus 10 is configured with one or a plurality of information processing apparatuses (computers) each including an arithmetic logic unit and a memory unit. Then, as shown in FIG. 1, the prediction model creation apparatus 10 includes a training data acquiring unit 11, a distribution estimating unit 12, a prediction model training unit 13, and a prediction model output unit 14. The respective functions of the training data acquiring unit 11, the distribution estimating unit 12, the prediction model training unit 13, and the prediction model output unit 14 can be enabled by execution of a program for enabling the functions stored in the memory unit by the arithmetic logic unit. Moreover, the prediction model creation apparatus 10 also includes a data storage unit 15 and a model storage unit 16. The data storage unit 15 and the model storage unit 16 are configured with the memory unit.

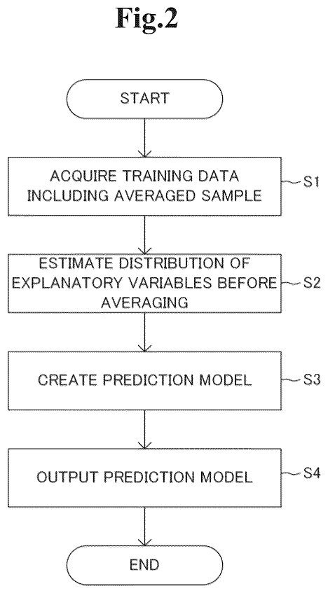

The training data acquiring unit 11 (acquiring unit) acquires training data including an averaged sample obtained by averaging a predetermined number of samples each composed of a pair of an explanatory variable and an objective variable (xᵢⱼ, yᵢⱼ) (step S1 in FIG. 2). Specifically, the training data acquiring unit 11 acquires training data D shown with Formula 1 by acquiring from an external device or reading from a storage medium, and stores it into the data storage unit 15. Here, an averaged sample shown in Formula 2 included by the training data D is created by averaging K pairs of raw data, namely, samples, as shown in Formula 3. That is to say, the explanatory variable and the objective variable in the averaged sample are expressed by Formula 4.

$$D = {\{ ( {\overline{x}}_{i} , {\overline{y}}_{i} ) \}}_{i = 1}^{n} \qquad [ Formula 1 ]$$

$$( {\overline{x}}_{i} , {\overline{y}}_{i} ) \qquad [ Formula 2 ]$$

$${\{ ( {x}_{ij} , {y}_{ij} ) \}}_{j = 1}^{K} \qquad [ Formula 3 ]$$

$${\overline{x}}_{i} = \frac{1}{K} {\sum }_{j = 1}^{K} {x}_{ij} , {\overline{y}}_{i} = \frac{1}{K} {\sum }_{j = 1}^{K} {y}_{ij} \qquad [ Formula 4 ]$$

Here, for example, K is a preset hyperparameter and is common in the training data D. As an example, K may be set to 2 or may be any other integer. Alternatively, K may be set to 1.5, and K is not limited to being an integer.

In this example embodiment, the pair of explanatory variable and objective variable (xij, yij) of each sample that is raw data is composed of, for example, an explanatory variable such as the age, annual income, saving deposit, place of work, years of service or the like of each individual before averaging and an objective variable such as loan approval or denial. That is to say, the raw data, namely, the sample is personal information that is an actual example. On the other hand, since the averaged sample is data obtained by averaging personal information that are a plurality of samples for each item, an individual cannot be identified from such data. For example, in a case where K=2 and the value of the explanatory variable of the averaged sample is 1, there may be infinite number of possible values as the raw data, such as (1, 1), (0, 2), (−1, 3), and (−0.5, 2.5). Therefore, in general, it is impossible to accurately restore each sample that is raw data from an averaged sample, and it can be said that there is no risk of leakage of personal information from such averaged data.

The training data acquiring unit 11 is not limited to acquiring an averaged sample that is the average of a plurality of samples of raw data from an external device or the like as described above, and may acquire samples of raw data from an external device or the like and generate an averaged sample from the acquired samples. At this time, the training data acquiring unit 11 acquires samples of raw data or stores into the data storage unit 15 in a way that prevents external leakage.

The distribution estimating unit 12 (estimating unit) estimates a pre-averaging distribution P, which is the distribution of pre-averaging explanatory variables corresponding to the explanatory variables composing the averaged samples that are the training data D acquired as described above (step S2 in FIG. 2). At this time, the distribution estimating unit 12 estimates the pre-averaging distribution P of the pre-averaging explanatory variables shown by Formula 6, based on the averaged explanatory variable composing the averaged sample shown by Formula 5.

$${\overline{x}}_{i} \qquad [ Formula 5 ]$$

$$P = p ( {x}_{i 1} , … , {x}_{iK} \vert {\overline{x}}_{i} ) \qquad [ Formula 6 ]$$

Specifically, using domain knowledge about the distribution of explanatory variables, the distribution estimating unit 12 estimates what a pre-averaging distribution that is the distribution of explanatory variables (xᵢ₁, . . . , x_{iK}) of samples before averaging is, based on a post-averaging distribution that is the distribution of explanatory variables of the averaged samples shown by Formula 5, when the explanatory variables of the averaged samples are given. For example, the distribution estimating unit estimates the pre-averaging distribution P as shown by Formula 7 using Bayes' theorem.

$$p ( {x}_{i 1} , … , {x}_{iK} \vert {\overline{x}}_{i} ) = \frac{[ {\overline{x}}_{i} = \frac{1}{K} {\sum }_{j = 1}^{K} {x}_{ij} ] p ( {x}_{i 1} , … , {x}_{iK} )}{p ( {\overline{x}}_{i} )} = \frac{[ {\overline{x}}_{i} = \frac{1}{K} {\sum }_{j = 1}^{K} {x}_{ij} ] {\prod }_{j = 1}^{K} p ( {x}_{ij} )}{p ( {\overline{x}}_{i} )} \qquad [ Formula 7 ]$$

As an example, in a case where a post-averaging distribution of the explanatory variables of the averaged sample shown in Formula 8 shown below follows a standard normal distribution, it can be estimated that xij, a pre-averaging distribution p of the explanatory variables of the pre-averaging samples follows a normal distribution with mean 0 and standard deviation 1/√K (Formula 9 shown below), and can be estimated as shown in Formula 10. In Formula 10, N(x; μ, σ²) represents the probability density of x in a normal distribution with mean μ and standard deviation σ.

$${\{ {\overline{x}}_{i} \}}_{i = 1}^{n} \qquad [ Formula 8 ]$$

$$\frac{1}{\sqrt{K}} \qquad [ Formula 9 ]$$

$$p ( {x}_{ij} ) = ( {x}_{ij} ; 0 , \frac{1}{K} ) \qquad [ Formula 10 ]$$

Here, particularly in a case where the averaged sample is averaged with K=2, it becomes possible to mathematically obtain the pre-averaging distribution P as follows. At this time, in a case where the post-averaging distribution of the explanatory variables of the averaged sample follows a normal distribution with mean 0 and standard deviation τ, it can be calculated as shown in Formula 11 and output as shown in Formula 12. Note that δ is the Kronecker delta function.

$$p ( {x}_{i 1} , {x}_{i 2} \vert {\overline{x}}_{i} ) = ( {x}_{i 1} ; {\overline{x}}_{i} , \frac{{τ}^{2}}{4} ) δ ( {\overline{x}}_{i} - \frac{{x}_{i 1} + {x}_{i 2}}{2} ) \qquad [ Formula 11 ]$$

$$P = {\{ ( {x}_{i 1} ; {\overline{x}}_{i} , \frac{{τ}^{2}}{4} ) δ ( {\overline{x}}_{i} - \frac{{x}_{i 1} + {x}_{i 2}}{2} ) \}}_{i = 1}^{K} \qquad [ Formula 12 ]$$

Moreover, as another example, in a case where the explanatory variables of the averaged sample shown in Formula 8 follows a uniform distribution, it can be estimated that xi also follows a uniform distribution. Moreover, as another example, in a case where the explanatory variables of the averaged sample shown in Formula 8 follows a binomial distribution, it can be estimated that xi follows a Bernoulli distribution. Even for a distribution other than a normal distribution, a mathematical calculation may be possible using the convolution of probability density function.

Since it may be difficult to accurately calculate the pre-averaging distribution p of the explanatory variables of the samples before averaging, the distribution estimating unit 12 may approximate the pre-averaging distribution by sampling P as will be described below. For example, the distribution estimating unit 12 generates sampling P through the following three processes using importance sampling.

### (Process 1)

Randomly generate T sets of (xᵢ₁, . . . , x_{iK}) according to p(xᵢ₁, . . . , x_{iK}), as shown in Formula 13.

$${\{ ( {x}_{i 1}^{( t )} , … , {x}_{iK}^{( t )} ) \}}_{t = 1}^{T} \qquad [ Formula 13 ]$$

### (Process 2)

Calculate a weight wᵢ^{(t)} as shown in Formula 14. Thus, calculate the relative likelihood in the sum of T sets as the weight wᵢ^{(t)}.

$${w}_{i}^{( t )} = \frac{p ( {x}_{i 1}^{( t )} , … , {x}_{iK}^{( t )} \vert {\overline{x}}_{i} )}{{\sum }_{s = 1}^{T} p ( {x}_{i 1}^{( t )} , … , {x}_{iK}^{( t )} \vert {\overline{x}}_{i} )} = \frac{[ {\overline{x}}_{i} = \frac{1}{K} {\sum }_{j = 1}^{K} {x}_{ij} ] {\prod }_{j = 1}^{K} p ( {x}_{ij}^{( t )} )}{{\sum }_{s = 1}^{T} [ {\overline{x}}_{i} = \frac{1}{K} {\sum }_{j = 1}^{K} {x}_{ij} ] {\prod }_{j = 1}^{K} p ( {x}_{ij}^{( t )} )} \qquad [ Formula 14 ]$$

### (Process 3)

Output Formula 15 as weighted sampling.

$$P = {\{ {\{ ( {w}_{i}^{( t )} , ( {x}_{i 1}^{( t )} , … , {x}_{iK}^{( t )} ) ) \}}_{t = 1}^{T} \}}_{i = 1}^{n} \qquad [ Formula 15 ]$$

As other approximation methods for the pre-averaging distribution, the MCMC method, the Metropolis-Hastings algorithm, Gibbs sampling, and so forth may be used.

The prediction model training unit 13 (training unit) creates a prediction model f that predicts an objective variable from an explanatory variable by performing machine learning on the prediction model f using the averaged sample that is the training data D described above and the pre-averaging distribution P estimated as described above (step S3 in FIG. 2). At this time, the prediction model training unit 13 first estimates an explanatory variable before averaging based on the pre-averaging distribution P from the explanatory variable composing the averaged sample that is the training data D. Then, the prediction model training unit 13 performs machine learning on the prediction model f in such a manner that the difference between a value based on an objective variable predicted using the prediction model f from the estimated explanatory variable before averaging and the objective variable composing the averaged sample that is the training data D.

More specifically, the prediction model training unit 13 performs machine learning on the prediction model f in such a manner as to minimize the negative log-likelihood L of the training data D, as shown in Formula 16 or Formula 17. As described above, in a case where the pre-averaging distribution P is given, L in Formula 16 is minimized, and in a case where sampling is given as an approximation of the pre-averaging distribution P, L in Formula 17 is minimized.

$$L : = - \frac{1}{n} {\sum }_{i = 1}^{n} log ( {𝔼}_{p ( {x}_{i 1} , … , {x}_{iK} \vert {\overline{x}}_{i} )} [ g ( \frac{1}{K} {\sum }_{j = 1}^{K} f ( {x}_{ij} ) , {\overline{y}}_{i} ) ] ) = - \frac{1}{n} {\sum }_{i = 1}^{n} log ( \int g ( \frac{1}{K} {\sum }_{j = 1}^{K} f ( {x}_{ij} ) , {\overline{y}}_{i} ) p ( {x}_{i 1} , … , {x}_{iK} \vert {\overline{x}}_{i} ) {dx}_{i 1} … {dx}_{iK} ) \qquad [ Formula 16 ]$$

$$L : = - \frac{1}{n} {\sum }_{i = 1}^{n} log ( {\sum }_{t = 1}^{T} {w}_{i}^{( t )} g ( \frac{1}{K} {\sum }_{j = 1}^{K} f ( {x}_{ij}^{( t )} ) , {\overline{y}}_{i} ) ) \qquad [ Formula 17 ]$$

A function g in Formulas 16 and 17 shown above is a function that calculates the probability of the objective variable of the averaged sample as shown in Formula 19 occurring with respect to the average of the objective variables yᵢⱼ that are output when the explanatory variables xᵢⱼ before averaging are input into the prediction model f shown in Formula 18, and the function outputs a value closer to 1 as the two are closer, and outputs a value closer to 0 when the two are farther apart.

$$\frac{1}{K} {\sum }_{j = 1}^{K} f ( {x}_{ij} ) \qquad [ Formula 18 ]$$

$${\overline{y}}_{i} \qquad [ Formula 19 ]$$

For example, the above function g can be expressed by Formula 20 in the case of regression, and can be expressed by Formula 21 in the case of classification, where f(x) outputs the prediction probability. Note that R is a hyperparameter and C is the number of classes.

$$g ( \frac{1}{K} {\sum }_{j = 1}^{K} f ( {x}_{ij} ) , {\overline{y}}_{i} ) = exp ( - \frac{( {\overline{y}}_{i} - \frac{1}{K} {\sum }_{j = 1}^{K} f ( {x}_{ij}^{( t )} ) )}{β} ) \qquad [ Formula 20 ]$$

$$g ( \frac{1}{K} {\sum }_{j = 1}^{K} f ( {x}_{ij} ) , {\overline{y}}_{i} ) = {\sum }_{b = 1}^{C} {( {( \frac{1}{K} {\sum }_{j = 1}^{K} f ( {x}_{ij} ) )}_{c} )}^{{\overline{y}}_{ic}} \qquad [ Formula 21 ]$$

Then, minimizing L described above is equivalent to training the prediction model f in such a manner that, after probabilistically estimating the explanatory variable xᵢⱼ before averaging from the averaged explanatory variable, the mean of the outputs yᵢⱼ for those explanatory variables xᵢⱼ matches the averaged objective variable.

As mentioned above, in minimizing L, it is also acceptable to calculate the upper limit of L and minimize that upper limit. For example, using Jensen's inequality, the right side of Formula 22 shown below may be minimized.

$$L \leq - \frac{1}{n} {\sum }_{i = 1}^{n} {𝔼}_{p ( {x}_{i 1} , … , {x}_{iK} \vert {\overline{x}}_{i} )} [ log ( g ( \frac{1}{K} {\sum }_{j = 1}^{K} f ( {x}_{ij} ) , {\overline{y}}_{i} ) ) ] \qquad [ Formula 22 ]$$

At this time, for example, in the case of regression, the right side of Formula 22 becomes Formula 23 shown below, so that the calculation becomes simpler by minimizing the right side

$$\frac{1}{n} {\sum }_{i = 1}^{n} {𝔼}_{p ( {x}_{i 1} , … , {x}_{iK} \vert {\overline{x}}_{i} )} [ \frac{{( {\overline{y}}_{i} - \frac{1}{K} {\sum }_{j = 1}^{K} f ( {x}_{ij}^{( t )} ) )}^{2}}{β} ] \qquad [ Formula 23 ]$$

Additionally, as another example, the prediction model f may be approximated by a simpler function, and L can be minimized based on that. For example, the calculation of L can be made to be more efficient by using Taylor Expansion of the prediction model f(x) near the explanatory variable of the averaged sample shown in Formula 24.

$${\overline{x}}_{i} \qquad [ Formula 24 ]$$

At this time, especially in the case of K=2, the odd dimensions of the Taylor Expansion become ±0 according to Formula 25, which may lead to more efficient calculations.

$$\frac{1}{2} {\sum }_{j = 1}^{2} f ( {x}_{ij}^{( t )} ) = \frac{f ( {\overline{x}}_{i} + ( {x}_{i 1} - {\overline{x}}_{i} ) ) + f ( {\overline{x}}_{i} - ( {x}_{i 1} - {\overline{x}}_{i} ) )}{2} \qquad [ Formula 25 ]$$

The prediction model output unit 14 outputs the created prediction model f to a prediction apparatus, which is another information processing apparatus (step S4 in FIG. 2), and stores it into the model storage unit 16 of the prediction model creation apparatus 10. Then, the created prediction model is used for prediction in the prediction apparatus to which the model is output or the prediction model creation apparatus 10. For example, by inputting an explanatory variable necessary for individual loan screening, such as an individual's age, annual income, saving deposit, place of work and years of service, into the created prediction model f, it is possible to obtain the output of an objective variable such as loan approval or denial. This enables supporting decision making by the user of the prediction model f, such as a person who conducts loan screening.

As described above, in the present disclosure, for creating the prediction model f, machine learning is performed using training data obtained by averaging raw data such as personal information. Therefore, there is no risk of leakage of raw data such as personal information from the training data itself or the prediction model, and it is possible to achieve increase of security. Further, for creating the prediction model f, machine learning is performed by estimating an explanatory variable before averaging from an averaged explanatory variable, so that the prediction model f with high accuracy can be created.

### Usage Example

Next, a usage example of the present disclosure will be described. Here, a case of predicting the length of stay until discharge for a patient with disease will be described as an example.

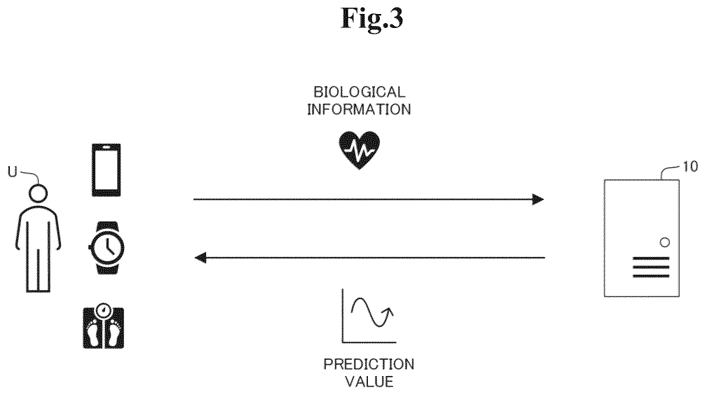

First, the prediction model creation apparatus 10 acquires, as information of a patient U who has already been discharged, a pair of the biological information of the patient U (an explanatory variable) and the length of stay until discharge (an objective variable) as the training data D. At this time, the prediction model creation apparatus 10 acquires an averaged sample that is the average of a plurality of pairs of biological information and length of stay until discharge. The biological Information of the patient U includes, for example, the age, gender, height, weight, occupation, blood type, medical history, genetic information, electronic medical record information of the patient U, as well as blood pressure, heart rate, and blood concentration measured using wearable devices and measuring instruments as shown in FIG. 3.

Next, the prediction model creation apparatus 10 estimates the pre-averaging distribution P, which is the distribution of explanatory variables before averaging corresponding to explanatory variables composing the averaged sample that is the training data D having been acquired. At this time, the prediction model creation apparatus 10 estimates the pre-averaging distribution that is the distribution of explanatory variables before averaging based on a post-averaging distribution, which is the distribution of explanatory variables of the averaged sample. Alternatively, the prediction model creation apparatus 10 may approximate the pre-averaging distribution by sampling by the aforementioned importance sampling method, for example.

Then, the prediction model creation apparatus 10 performs machine learning on the prediction model f that predicts an objective variable from an explanatory variable using the averaged sample as the training data D and the estimated pre-averaging distribution P, thereby creating the prediction model f. Specifically, the prediction model creation apparatus 10 estimates the explanatory variable before averaging based on the pre-averaging distribution P from the explanatory variables composing the averaged sample that is the training data D. Then, the prediction model creation apparatus 10 performs machine learning on the prediction model f in such a manner as to minimize the difference between the objective variable predicted using the prediction model f from the estimated explanatory variable before averaging and the objective variable composing the averaged sample that is the training data D. In this manner, it is possible to create the prediction model f that predicts the length of stay until discharge from the biological information of the patient U.

After that, by inputting the biological information of a newly hospitalized patient U into the created prediction model f, it is possible to predict the length of stay until discharge of that patient U. This can support decision making by medical professionals such as doctors.

As described above, by creating the prediction model f through machine learning using training data obtained by averaging raw data such as personal information, it is possible to achieve increase of security with no risk of leakage of raw data such as personal information from the training data itself or the prediction model. Further, for creating the prediction model f, the explanatory variable before averaging is estimated from the averaged explanatory variable and machine learning is performed, so that the prediction model f with high accuracy can also be created. The abovementioned usage example of the prediction model creation apparatus 10 is just one example, and it may be used to create any kind of prediction model.

### Second Example Embodiment

Next, a second example embodiment of the present disclosure will be described with reference to the drawings. This example embodiment shows the overview of the prediction model creation apparatus and so forth described in the above example embodiment. The drawings may be related to any of the example embodiments.

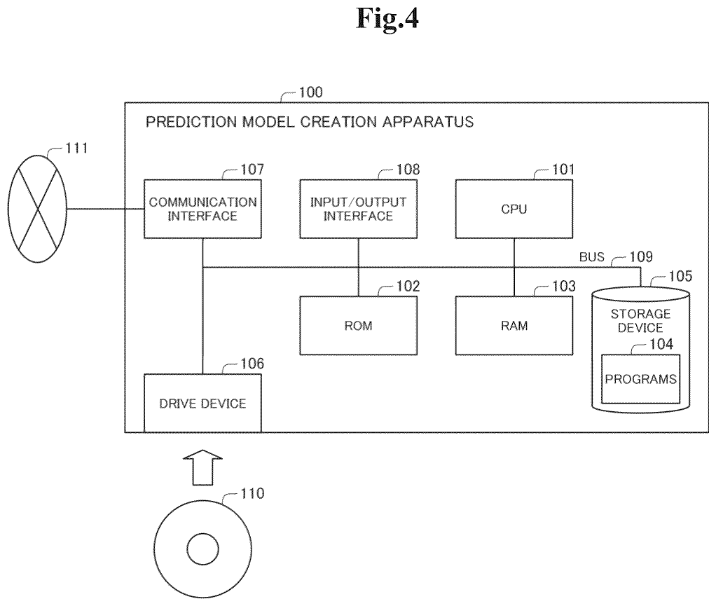

First, a hardware configuration of a prediction model creation apparatus 100 in the present disclosure will be described. The prediction model creation apparatus 100 is configured with a general information processing apparatus, and as an example, as shown in FIG. 4, has the following hardware configuration including:
a CPU (Central Processing Unit) 101 (arithmetic logic unit);
a ROM (Read Only Memory) 102 (memory unit);
a RAM (Random Access Memory) 103 (memory unit);
programs 104 loaded into the RAM 103;
a storage device 105 storing the programs 104;
a drive device 106 that performs reading from and writing into a storage medium 110 external to the information processing apparatus;
a communication interface 107 connected to a communication network 111 external to the information processing apparatus;
an input/output interface 108 that performs input/output of data; and
a bus 109 connecting the components.

FIG. 4 shows an example of the hardware configuration of the information processing apparatus serving as the prediction model creation apparatus 100, and the hardware configuration of the information processing apparatus is not limited to the abovementioned case. For example, the information processing apparatus may be configured with part of the abovementioned configuration, such as not having the drive device 106. Moreover, the information processing apparatus may use a GPU (Graphic Processing Unit), a DSP (Digital Signal Processor), an MPU (Micro Processing Unit), an FPU (Floating point number Processing Unit), a PPU (Physics Processing Unit), a TPU (Tensor Processing Unit), a quantum processor, a microcontroller, or a combination of these, instead of the abovementioned CPU.

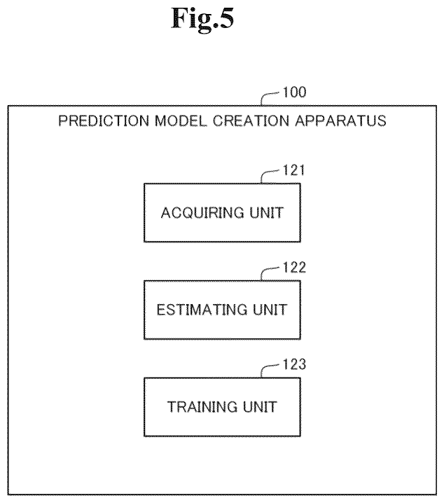

Then, the prediction model creation apparatus 100 can construct and include an acquiring unit 121, an estimating unit 122, and a training unit 123 shown in FIG. 5 by acquisition and execution of the programs 104 by the CPU 101. The programs 104 are, for example, stored in advance in the storage device 105 or the ROM 102, and are loaded into the RAM 103 and executed by the CPU 101 as necessary. In addition, the programs 104 may be provided to the CPU 101 via the communication network 111, or the programs may be stored in advance in the storage medium 110 and read out by the drive device 106 and provided to the CPU 101. However, the acquiring unit 121, the estimating unit 122, and the training unit 123 may be constructed using dedicated electronic circuits for implementing such means.

The acquiring unit 121 acquires training data including an averaged sample obtained by averaging a plurality of samples each composed of a pair of an explanatory variable and an objective variable. The estimating unit 122 estimates a pre-averaging distribution that is a distribution of explanatory variables before averaging corresponding to the explanatory variables composing the averaged sample of the training data. The training unit 123 performs machine learning on a prediction model that predicts an objective variable from an explanatory variable based on the training data and the pre-averaging distribution.

Configured as described above, the present disclosure creates a prediction model by machine learning using training data obtained by averaging raw data such as personal information. Consequently, there is no risk of leakage of the raw data such as personal information from the training data itself and the prediction model, and enhancement in security can be achieved. Further, it is also possible to create the prediction model with high accuracy because for creating the prediction model, an explanatory variable before averaging is estimated from an averaged explanatory variable and then machine learning is performed.

At least one or more functions of the functions of the acquiring unit 121, the estimating unit 122, and the training unit 123 described above may be executed by an information processing apparatus installed and connected anywhere on the network, that is, may be executed by so-called cloud computing.

Further, the abovementioned programs can be stored using various types of non-transitory computer-readable mediums and provided to a computer. The non-transitory computer-readable medium includes various types of tangible storage mediums. Examples of non-transitory computer-readable medium include magnetic recording medium (e.g., flexible disk, magnetic tape, hard disk drive), magneto-optical recording medium (e.g., magneto-optical disk), read only memory (CD-ROM), CD-R, CD-R/W, semiconductor memory (e.g., mask ROM, programmable ROM, Erasable PROM, flash ROM, random access memory (RAM)). In addition, a program may be provided to a computer by various types of temporary computer-readable medium. Examples of temporary computer-readable medium include electrical signals, optical signals, and electromagnetic waves. The temporary computer-readable medium may provide a program to the computer via a wired communication channel, such as an electric wire and an optical fiber, or a wireless communication channel.

Although the present disclosure has been described above with reference to example embodiments, the present disclosure is not limited to the example embodiments described above. The configuration and details of the present disclosure can be changed in a variety of ways that those skilled in the art can understand within the scope of the present disclosure. Then, each of the example embodiments described above can be combined with the other example embodiment as necessary.

### <Supplementary Notes>

The whole or part of the example embodiments disclosed above can be described as the following supplementary notes. Hereinafter, the overview of configurations of a prediction model creation apparatus, a prediction model creation method, and a program in the present disclosure will be described. However, the present disclosure is not limited to the configurations described in the following supplementary notes.

All or some of the configurations described in Supplementary Notes 2 to 8 dependent on Supplementary Note 1 described below and the functions by such configurations may be dependent on other Supplementary Notes 9 and 10 by the same dependence as Supplementary Notes 2 to 8. Furthermore, not limited to Supplementary Notes 1, 9, or 10, within the scope of the example embodiments described above, all or some of the configurations described as supplementary notes and functions by such configurations may be dependent on hardware, software, various recording means for recording software, or system.

### (Supplementary Note 1)

A prediction model creation apparatus comprising:
an acquiring unit configured to acquire training data including averaged samples each obtained by averaging a plurality of samples each composed of a pair of an explanatory variable and an objective variable;
an estimating unit configured to estimate a pre-averaging distribution that is a distribution of explanatory variables before averaging corresponding to explanatory variables composing the averaged samples of the training data; and
a training unit configured to perform machine learning on a prediction model that predicts an objective variable from an explanatory variable, based on the training data and the pre-averaging distribution.

### (Supplementary Note 2)

The prediction model creation apparatus according to supplementary note 1, wherein
the training unit is configured to perform machine learning on the prediction model, using the explanatory variables before averaging estimated based on the pre-averaging distribution from the explanatory variables composing the averaged samples of the training data, and using objective variables composing the averaged samples of the training data.

### (Supplementary Note 3)

The prediction model creation apparatus according to supplementary note 2, wherein
the training unit is configured to perform machine learning on the prediction model in such a manner that a difference between a value based on the objective variables predicted using the prediction model from the estimated explanatory variables before averaging and the objective variables composing the averaged samples of the training data becomes small.

### (Supplementary Note 4)

The prediction model creation apparatus according to supplementary note 2, wherein
the training unit is configured to perform machine learning on the prediction model in such a manner as to minimize a difference between a mean value of the objective variables predicted using the prediction model from the estimated explanatory variables before averaging and the objective variable composing the averaged sample of the training data.

### (Supplementary Note 5)

The prediction model creation apparatus according to supplementary note 1, wherein
the estimating unit is configured to estimate the pre-averaging distribution based on a post-averaging distribution that is a distribution of the explanatory variables composing the averaged samples of the training data.

### (Supplementary Note 6)

The prediction model creation apparatus according to supplementary note 1, wherein
the estimating unit is configured to estimate the pre-averaging distribution in such a manner that the explanatory variables before averaging of the explanatory variables composing the averaged samples of the training data follow a normal distribution.

### (Supplementary Note 7)

The prediction model creation apparatus according to supplementary note 1, wherein
the estimating unit is configured to estimate by approximating the pre-averaging distribution by weighted sampling of the explanatory variables before averaging of the explanatory variables composing the averaged samples of the training data.

### (Supplementary Note 8)

The prediction model creation apparatus according to supplementary note 1, wherein
the acquiring unit is configured to acquire the training data including the averaged samples obtained by averaging two samples each composed of a pair of an explanatory variable and an objective variable.

### (Supplementary Note 9)

A prediction model creation method comprising:
acquiring training data including averaged samples each obtained by averaging a plurality of samples each composed of a pair of an explanatory variable and an objective variable;
estimating a pre-averaging distribution that is a distribution of explanatory variables before averaging corresponding to explanatory variables composing the averaged samples of the training data; and
performing machine learning on a prediction model that predicts an objective variable from an explanatory variable, based on the training data and the pre-averaging distribution.

### (Supplementary Note 10)

The prediction model creation method according to supplementary note 9, comprising
performing machine learning on the prediction model, using the explanatory variables before averaging estimated based on the pre-averaging distribution from the explanatory variables composing the averaged samples of the training data, and using objective variables composing the averaged samples of the training data.

### (Supplementary Note 11)

The prediction model creation method according to supplementary note 10, comprising
performing machine learning on the prediction model in such a manner that a difference between a value based on the objective variables predicted using the prediction model from the estimated explanatory variables before averaging and the objective variables composing the averaged samples of the training data becomes small.

### (Supplementary Note 12)

The prediction model creation method according to supplementary note 10, comprising
performing machine learning on the prediction model in such a manner as to minimize a difference between a mean value of the objective variables predicted using the prediction model from the estimated explanatory variables before averaging and the objective variable composing the averaged sample of the training data.

### (Supplementary Note 13)

The prediction model creation method according to supplementary note 9, comprising
estimating the pre-averaging distribution based on a post-averaging distribution that is a distribution of the explanatory variables composing the averaged samples of the training data.

### (Supplementary Note 14)

The prediction model creation method according to supplementary note 9, comprising
estimating the pre-averaging distribution in such a manner that the explanatory variables before averaging of the explanatory variables composing the averaged samples of the training data follow a normal distribution.

### (Supplementary Note 15)

The prediction model creation method according to supplementary note 9, comprising
estimating by approximating the pre-averaging distribution by weighted sampling of the explanatory variables before averaging of the explanatory variables composing the averaged samples of the training data.

### (Supplementary Note 16)

The prediction model creation method according to supplementary note 9, comprising
acquiring the training data including the averaged samples obtained by averaging two samples each composed of a pair of an explanatory variable and an objective variable.

### (Supplementary Note 17)

A program comprising instructions for causing a computer to execute processes to:
acquire training data including averaged samples each obtained by averaging a plurality of samples each composed of a pair of an explanatory variable and an objective variable;
estimate a pre-averaging distribution that is a distribution of explanatory variables before averaging corresponding to explanatory variables composing the averaged samples of the training data; and
perform machine learning on a prediction model that predicts an objective variable from an explanatory variable, based on the training data and the pre-averaging distribution.

### REFERENCE SIGNS LIST

10 prediction model creation apparatus
11 training data acquiring unit
12 distribution estimating unit
13 prediction model training unit
14 prediction model output unit
15 data storage unit
16 model storage unit
100 prediction model creation apparatus
101 CPU
102 ROM
103 RAM
104 programs
105 storage device
106 drive device
107 communication interface
108 input/output interface
109 bus
110 storage medium
111 communication network
121 acquiring unit
122 estimating unit
123 training unit

1. A prediction model creation apparatus comprising:
at least one memory storing processing instructions; and
at least one processor configured to execute the processing instructions to:
acquire training data including averaged samples each obtained by averaging a plurality of samples each composed of a pair of an explanatory variable and an objective variable;
estimate a pre-averaging distribution that is a distribution of explanatory variables before averaging corresponding to explanatory variables composing the averaged samples of the training data; and
perform machine learning on a prediction model that predicts an objective variable from an explanatory variable, based on the training data and the pre-averaging distribution.

2. The prediction model creation apparatus according to claim 1, wherein the at least one processor is configured to execute the processing instructions to
perform machine learning on the prediction model, using the explanatory variables before averaging estimated based on the pre-averaging distribution from the explanatory variables composing the averaged samples of the training data, and using objective variables composing the averaged samples of the training data.

3. The prediction model creation apparatus according to claim 2, wherein the at least one processor is configured to execute the processing instructions to
perform machine learning on the prediction model in such a manner that a difference between a value based on the objective variables predicted using the prediction model from the estimated explanatory variables before averaging and the objective variables composing the averaged samples of the training data becomes small.

4. The prediction model creation apparatus according to claim 2, wherein the at least one processor is configured to execute the processing instructions to
perform machine learning on the prediction model in such a manner as to minimize a difference between a mean value of the objective variables predicted using the prediction model from the estimated explanatory variables before averaging and the objective variable composing the averaged sample of the training data.

5. The prediction model creation apparatus according to claim 1, wherein the at least one processor is configured to execute the processing instructions to
estimate the pre-averaging distribution based on a post-averaging distribution that is a distribution of the explanatory variables composing the averaged samples of the training data.

6. The prediction model creation apparatus according to claim 1, wherein the at least one processor is configured to execute the processing instructions to
estimate the pre-averaging distribution in such a manner that the explanatory variables before averaging of the explanatory variables composing the averaged samples of the training data follow a normal distribution.

7. The prediction model creation apparatus according to claim 1, wherein the at least one processor is configured to execute the processing instructions to
estimate by approximating the pre-averaging distribution by weighted sampling of the explanatory variables before averaging of the explanatory variables composing the averaged samples of the training data.

8. The prediction model creation apparatus according to claim 1, wherein the at least one processor is configured to execute the processing instructions to
acquire the training data including the averaged samples obtained by averaging two samples each composed of a pair of an explanatory variable and an objective variable.

9. A prediction model creation method comprising:
acquiring training data including averaged samples each obtained by averaging a plurality of samples each composed of a pair of an explanatory variable and an objective variable;
estimating a pre-averaging distribution that is a distribution of explanatory variables before averaging corresponding to explanatory variables composing the averaged samples of the training data; and
performing machine learning on a prediction model that predicts an objective variable from an explanatory variable, based on the training data and the pre-averaging distribution.

10. The prediction model creation method according to claim 9, comprising
performing machine learning on the prediction model, using the explanatory variables before averaging estimated based on the pre-averaging distribution from the explanatory variables composing the averaged samples of the training data, and using objective variables composing the averaged samples of the training data.

11. The prediction model creation method according to claim 10, comprising
performing machine learning on the prediction model in such a manner that a difference between a value based on the objective variables predicted using the prediction model from the estimated explanatory variables before averaging and the objective variables composing the averaged samples of the training data becomes small.

12. The prediction model creation method according to claim 10, comprising
performing machine learning on the prediction model in such a manner as to minimize a difference between a mean value of the objective variables predicted using the prediction model from the estimated explanatory variables before averaging and the objective variable composing the averaged sample of the training data.

13. The prediction model creation method according to claim 9, comprising
estimating the pre-averaging distribution based on a post-averaging distribution that is a distribution of the explanatory variables composing the averaged samples of the training data.

14. The prediction model creation method according to claim 9, comprising
estimating the pre-averaging distribution in such a manner that the explanatory variables before averaging of the explanatory variables composing the averaged samples of the training data follow a normal distribution.

15. The prediction model creation method according to claim 9, comprising
estimating by approximating the pre-averaging distribution by weighted sampling of the explanatory variables before averaging of the explanatory variables composing the averaged samples of the training data.

16. The prediction model creation method according to claim 9, comprising
acquiring the training data including the averaged samples obtained by averaging two samples each composed of a pair of an explanatory variable and an objective variable.

17. A non-transitory computer-readable storage medium storing a program, the program comprising instructions for causing a computer to execute processes to:
acquire training data including averaged samples each obtained by averaging a plurality of samples each composed of a pair of an explanatory variable and an objective variable;
estimate a pre-averaging distribution that is a distribution of explanatory variables before averaging corresponding to explanatory variables composing the averaged samples of the training data; and
perform machine learning on a prediction model that predicts an objective variable from an explanatory variable, based on the training data and the pre-averaging distribution.
